(19) United States
(12) Patent Application Publication
(10) Pub. No.: US 2026/0314142 A1
(43) Pub. Date: Oct. 8, 2026

(54) MICRO-LED DISPLAY DRIVE CIRCUITS

(71) Applicant: Tectus Corporation, Cupertino, CA (US)

(72) Inventors: Cary Loren DELANO, Los Altos, CA (US); Pritika DANDRIYAL, San Jose, CA (US); Ion OPRIS, San Jose, CA (US)

(21) Appl. No.: 19/442,997

(22) Filed: Jan. 7, 2026

Related U.S. Application Data
(60) Provisional application No. 63/743,390, filed on Jan. 9, 2025.

(51) Int. Cl. H10H 29/32

(52) U.S. Cl. CPC H10H 29/32

(57) ABSTRACT

A light-emitting diode (LED) display, with improved uniformity of illumination. In some embodiments, the display includes: an array 120 of GaN backplane 110, the array being hybrid bonded to the CMOS backplane, the array including a first LED 405, the CMOS backplane including: a first current source circuit; and a gate control circuit, the first current source circuit including: an n-channel field effect transistor 505; and a p-channel field effect transistor 510, the n-channel field effect transistor, the p-channel field effect transistor, and the first LED being connected in series, the source of the n-channel field effect transistor being connected to the source of the p-channel field effect transistor, the gate control circuit having a first output connected to the gate of the n-channel field effect transistor and a second output connected to the gate of the p-channel field effect transistor.

### CROSS-REFERENCE TO RELATED APPLICATION(S)

The present application claims priority to and the benefit of U.S. Provisional Application No. 63/743,390, filed Jan. 9, 2025, entitled “MICRO-LED DISPLAY DRIVE CIRCUITS”, the entire content of which is incorporated herein by reference.

### BACKGROUND

Demand for color displays, for TVs, tablets, cell phones and future applications such as augmented reality glasses, is insatiable. In particular there is high demand for small, bright and efficient color displays, better than those that exist today. Hence there is a great need for new displays and methods of manufacturing them.

### BRIEF DESCRIPTION OF THE DRAWINGS

FIG. 1 is an exploded perspective diagram of a micro-LED display chip.

FIG. 2 is a diagram illustrating the effect of supply voltage variation in a micro-LED display chip.

FIG. 3 illustrates pulse width modulation and pulse amplitude modulation.

FIG. 4 is a schematic diagram of a micro-LED power supply circuit.

FIG. 5 is a schematic diagram of a micro-LED power supply circuit.

FIG. 6 is a schematic diagram of a micro-LED power supply circuit.

FIG. 7 illustrates modulated power supply voltages for micro-LEDs.

FIG. 8 illustrates the effect of including both pre-bias and fixed bias current sources in the circuit of FIG. 6.

### DETAILED DESCRIPTION

A micro-LED display chip has a light-emission layer and a backplane layer. The light emission layer may be an array of LEDs, e.g. with GaN quantum well active layers, which are fabricated on a GaN-on-sapphire or GaN-on-Si substrate. The backplane may be fabricated on a Si CMOS wafer. The two wafers may then be hybrid bonded together so that CMOS circuitry may provide drive current to the LEDs. Generally, the term “micro-LED” means that the size of a display pixel is very small. The pitch, or distance from the edge of one pixel to the corresponding edge of its nearest neighbor may also be very small. For example, micro-LEDs may be as small as about 1 μm-10 μm or less and laid out with a pitch of about 1 μm-10 μm or less. When front-and backplane wafers are bonded together to form pixels, the CMOS driver may be confined to the same wafer area as the LED.

Within the backplane, pixel driver circuits supply and control current to individual display pixels to vary their brightness. The current may be varied via pulse amplitude modulation (PAM), pulse width modulation (PWM) or a combination of the two techniques. In some implementations PAM is used to control the brightness of the display as a whole, while PWM is used to control the brightness of individual pixels.

PAM relies on high-resolution DACs and is therefore impractical to implement for individual pixels. PWM, on the other hand, may be implemented in CMOS digital circuits in a very small area. CMOS technology nodes are now so small that each display pixel may have its own SRAM memory, and that enables each pixel to have its own PWM driver circuit. However, the driver circuit cannot take up too much area, especially when the pixel size is about 1 μm-10 μm or less. The available area is further reduced by a factor of three when separate drivers are needed for red, green and blue subpixels within each pixel.

A compact pixel driver minimizes die area by taking advantage of certain properties of a display clock signal which permit simplified PWM generation in each pixel. See, e.g., “Compact pixel driver”, U.S. Pat. No. 12,067,933, issued Aug. 20, 2024, incorporated herein by reference.

Micro-LED display drive circuits may be further optimized to provide improved brightness uniformity and dynamic range.

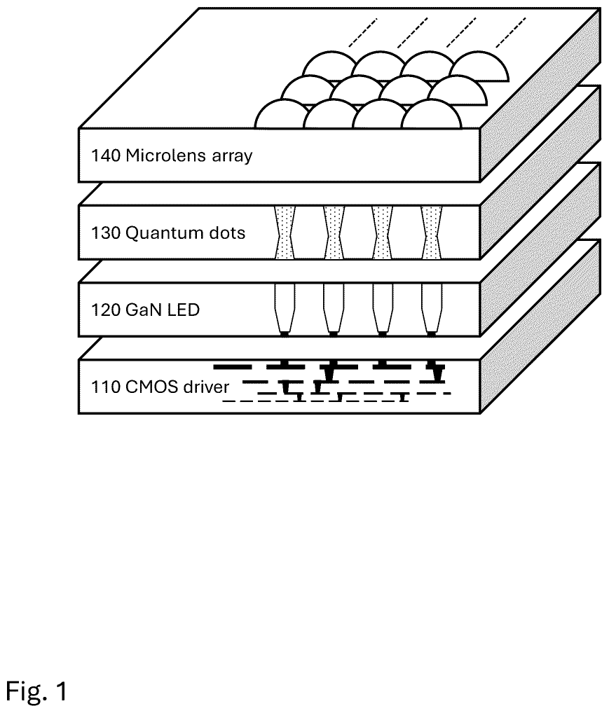

FIG. 1 is an exploded perspective diagram of a micro-LED display chip. The chip includes a layer 120 of GaN LEDs hybrid bonded to a CMOS driver layer 110. An optional, quantum-dot color conversion layer 130 may convert light from blue LEDs to red or green, for example. An optional microlens array layer 140 improves coupling of light from the micro-LED display chip into a downstream optics acceptance cone (not illustrated).

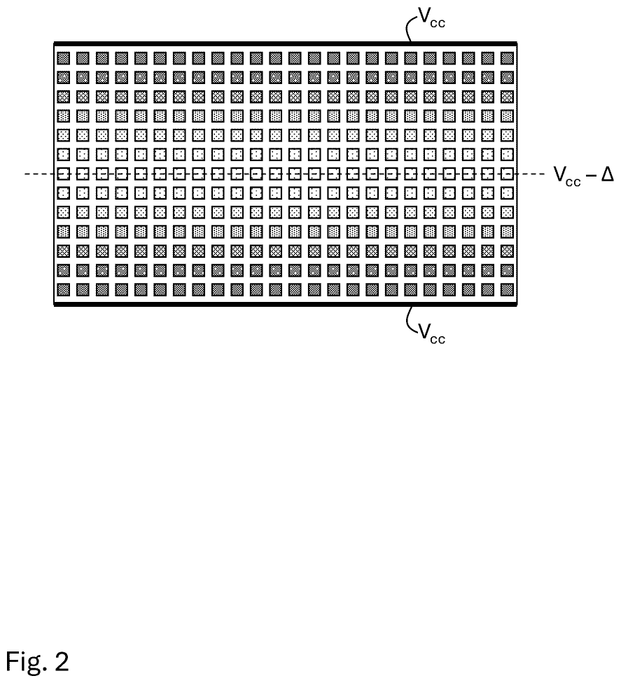

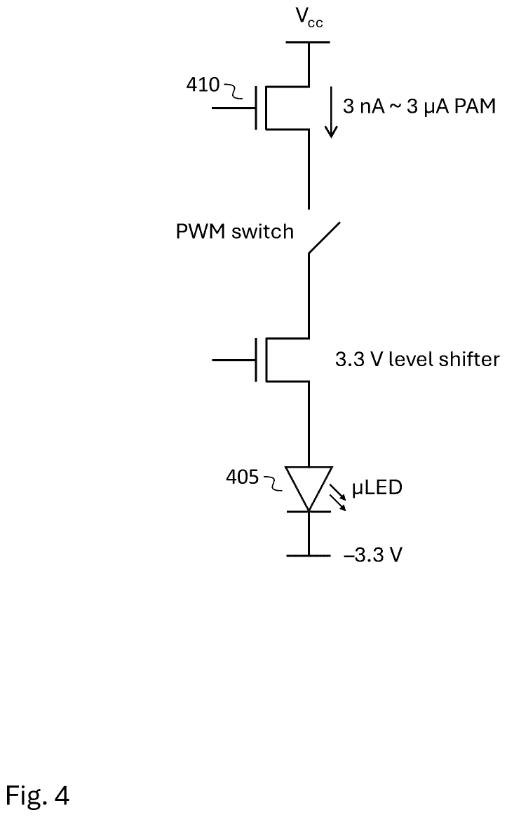

FIG. 2 is a diagram illustrating the effect of supply voltage variation in a micro-LED display chip. Resistance between the center and the edges of the display chip leads to spatially non-uniform drive voltage and pixel brightness. In this example, resistance across a micro-LED display chip reduces the supply voltage, V_{cc}, from about 3 V at the edges of the chip to about 2.99 V near the center of the chip. (In this example, the difference Δ may be about 10 mV.) This small variation in V_{cc} is significant because it changes the voltage (e.g., the gate-source voltage) applied to voltage-to-current converters, such as the current drive illustrated in FIG. 4. Small voltage changes may lead to large current changes and therefore large changes in emitted light level.

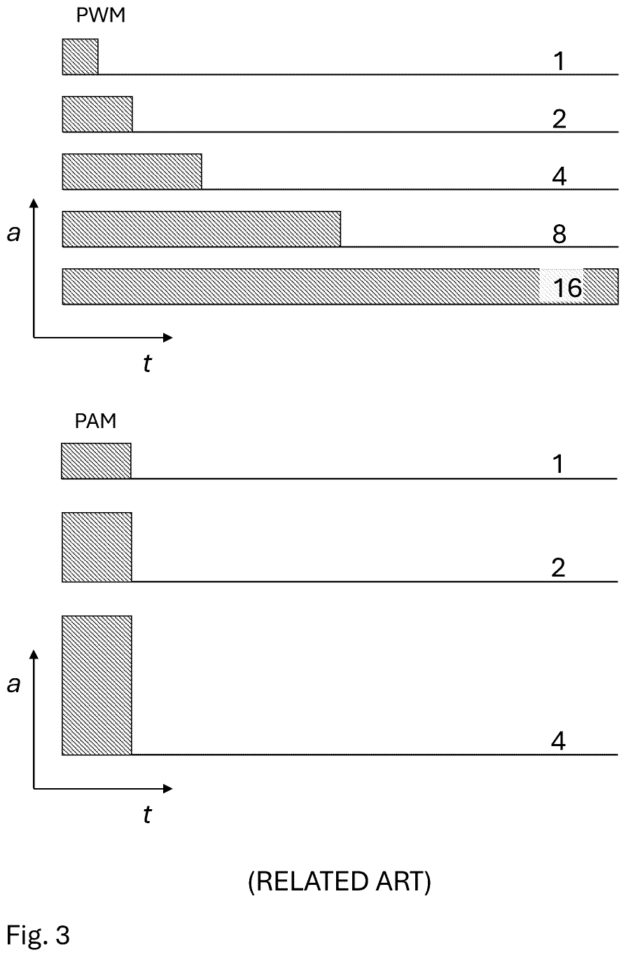

FIG. 3 illustrates pulse width modulation (PWM) and pulse amplitude modulation (PAM). In PWM the temporal width (e.g., the duration) of micro-LED drive pulses is varied to change the apparent brightness of a pixel. The brightness may be varied in a binary coding scheme. For example, brightness level 11 may be achieved by turning on a pixel for 8 time units, 2 time units and 1 time unit during a display frame time. The micro-LED drive signal need not remain on continuously for 11 time units during the frame as the human visual system naturally integrates light with a time constant of several tens of milliseconds.

In PAM the voltage or current amplitude of micro-LED drive pulses is varied to change the apparent brightness of a pixel. The brightness may be varied in a binary coding scheme. For example, brightness level 3 may be achieved by adding currents produced for brightness level 1 and brightness level 2.

PWM may be used to control the brightness of individual pixels while PAM controls the brightness of the display as a whole, or the brightness of separate red, green and blue channels in the display.

FIG. 4 is a schematic diagram of a micro-LED power supply circuit for supplying current to a light-emitting diode 405. A PWM switching mechanism forms pulses to drive an individual pixel. A PAM switch 410 (which may be a p-channel field effect transistor) selects drive currents ranging from about 3 nA to about 3 μA for the display as a whole. The circuit of FIG. 4 may have insufficient power supply rejection ratio (PSRR) for micro-LED display purposes. In other words, the power supply voltage decreases too rapidly as the current drawn from the power supply increases, or the effect of changes in the power supply voltage on the PAM current is too great, leading to unwanted PAM current variations.

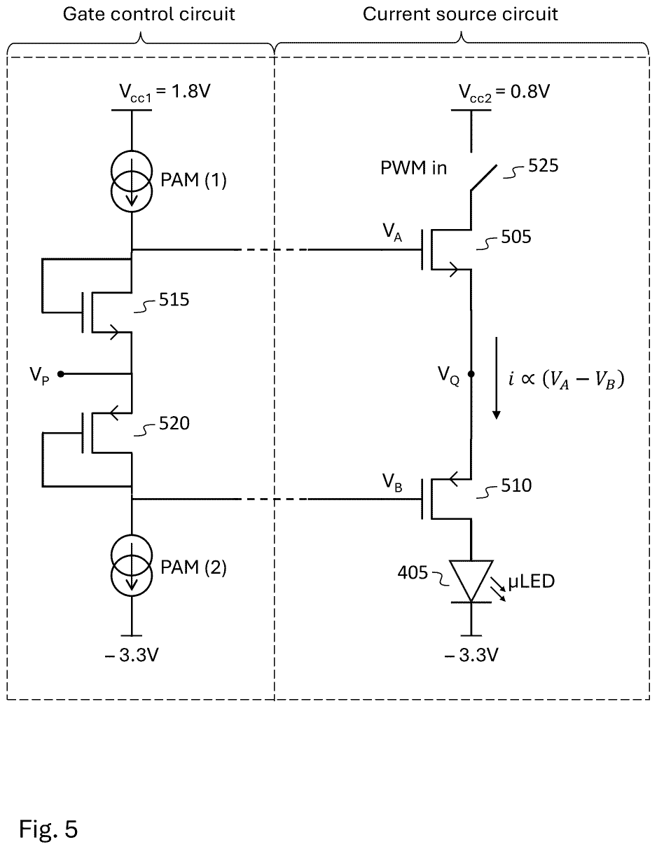

FIG. 5 is a schematic diagram of a micro-LED power supply circuit. The circuit of FIG. 5 includes a gate control circuit (the left-hand portion of the circuit) that provides a differential bias to a current source circuit (which includes an n-channel field effect transistor 505 and a p-channel field effect transistor 510). The PAM current (e.g., the current that flows through the current source circuit and the micro-LED 405) may be determined primarily by (e.g., may be proportional to) the differential bias (V_{A}-VB) applied the gates of the transistors 505, 510. Any changes in the supply voltage may affect V_{A} and V_{B} substantially equally; as such, the current flowing through the micro-LED when the PWM switch is closed may be substantially unaffected by changes in the supply voltage. One or more LEDs or (e.g., each row of) a micro-LED array such as that illustrated in FIG. 2 may be served by the gate control circuit of FIG. 5. In some embodiments, the LEDs served by a gate control circuit include a row of the display, or a column of the display, or a quadrant of the display, or any other portion of the display (e.g., the entire display). In the gate control circuit, PAM signals are applied to current sources “PAM (1)” and “PAM (2)”. The PAM (1) and PAM (2) current sources are designed to be the same and to take the same PAM input signal at the same time. However, a mismatch of up to about 10% between the PAM (1) and PAM (2) outputs is acceptable as any error current is sunk in the V_{P} node. Node V_{P} is maintained at a voltage intermediate between V_{cc} and the −3.3 V rail. (Node V_{P} may be moved to the top of the diode-connected NFET 515 or the bottom of the diode-connected PFET 520 if the bias is adjusted accordingly.)

The PAM signals in the gate control circuit section set voltages at the gates of the transistors 505, 510 of the current source circuit section of the circuit. A copy of the current source circuit is provided at each pixel in the display. A “PWM in” switch 525 in the “current source circuit” section modulates the current to a micro-LED ON or OFF. As mentioned above, when the “PWM in” switch is ON, the amplitude of the current is proportional to the voltage difference V_{A}-V_{B}.

In FIG. 5, node V_{Q} has the same voltage as node V_{P}. The transistors 505, 510 of the current source circuit may be high voltage transistors (e.g. 1.8 V rather than 0.8 V). The voltage at node V_{P} prevents the p-channel field effect transistor 510 of the current source circuit from breaking down.

The power supply rejection ratio of the circuit of FIG. 5 is about ten times (or more) better than that of the circuit of FIG. 4 for local V_{CC} variations (assuming that the gate voltage of the PAM transistor is constant). The differential bias design reduces the effect of voltage sag; this effect is illustrated in FIG. 2 and is attributable to the shortcomings of a circuit like that shown in FIG. 4.

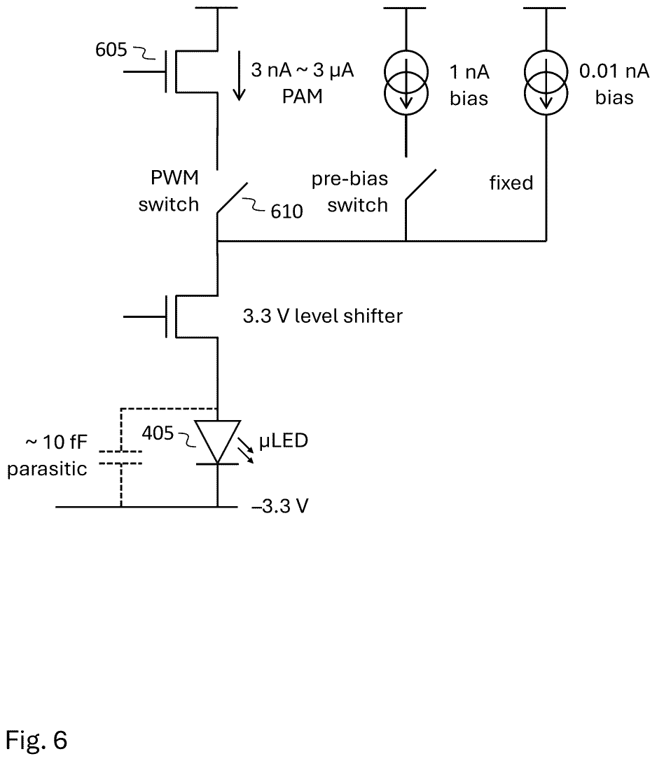

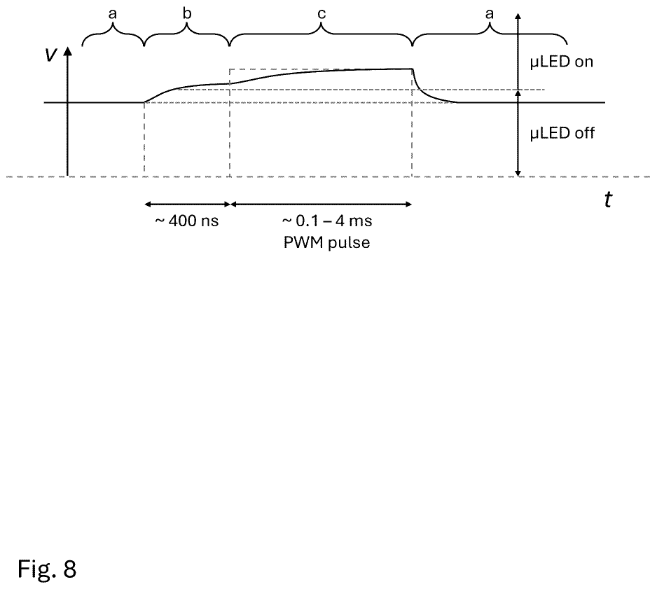

FIG. 6 is a schematic diagram of a micro-LED power supply circuit. The circuit of FIG. 6 includes two bias current supplies which charge up the small parasitic capacitance of each micro-LED between “on” pulses, for reasons explained below. The circuit of FIG. 6 may be compared to the current source circuit of the circuit of FIG. 5, or to FIG. 4. In FIG. 6 PAM controls an approximately 3 nA to approximately 3 μA current source implemented using a PAM transistor 605, while a PWM switch further modulates the current to adjust micro-LED brightness. In FIG. 6 the differential bias PAM design is omitted for simplicity, but small bias current supplies may be incorporated in the current source circuit of a circuit like that shown in FIG. 5; for example, these bias supplies may be connected to (and supply current to) the node between the PWM switch and the n-channel field effect transistor 505 of the current source circuit of FIG. 5. In other words, fixed and pre-bias current sources may be added in parallel to the “PWM in” switch. When the “PWM in” switch is OFF, the n-channel field effect transistor 505 goes into the resistive region but still faithfully passes the fixed and pre-bias currents to the micro-LED. Similarly, in FIG. 6, when the PWM switch 610 is open, the fixed and pre-bias currents may continue to flow to the micro-LED. One of the small bias current supplies provides approximately 1 nA and is controlled by a pre-bias switch. Another small, fixed bias current supply provides approximately 0.01 nA and is “always on”. The operation and effect of the pre-bias and fixed bias current supplies is discussed in connection with FIG. 8 below.

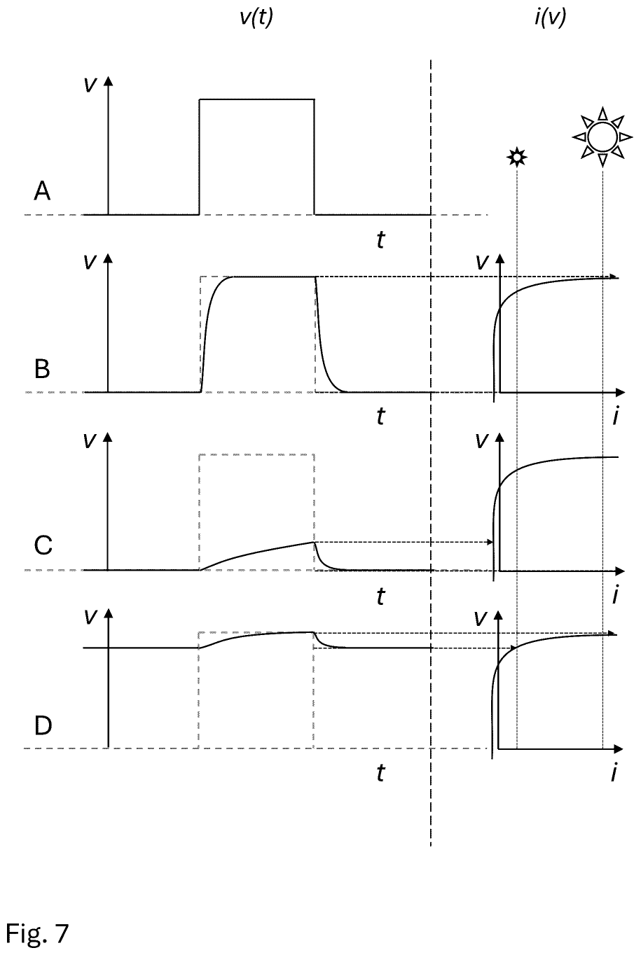

FIG. 7 illustrates pulse-width-modulated power supply voltages for micro-LEDs. An ideal, square shaped voltage pulse applied across the micro-LED, v(t), with instantaneous rising and falling edges, is shown at “A”. At “B” a realistic, nearly square voltage pulse is illustrated. The curvature in the rising and falling edges of the v(t) waveform is caused by the ~10 fF parasitic capacitance illustrated in FIG. 6 and the nonlinear i(v) transfer function of the micro-LED itself. The right side (to the right of the vertical dashed line) of the diagram shows a current versus voltage curve for a micro-LED. It is apparent that as the voltage across a micro-LED rises, initially little current flows, but as the voltage continues to rise, current flow increases rapidly. The curve is highly nonlinear. Light output from the micro-LED is proportional to the current flow as suggested by small and large sun icons which annotate the i(v) curve. The situation at “B” is obtained when the PAM contribution to a PAM+PWM modulation scheme is large and overall display brightness is high.

When overall display brightness is low and the PAM part of a PAM+PWM modulation signal is small, there may not be enough time for small PWM signals to charge the capacitance of a micro-LED. This leads to low, or no, light output and poor dynamic range. This situation is illustrated at “C”. There is not enough time available for small drive currents to charge the micro-LED capacitance and the v(t) waveform does not have time to form a shape resembling a square wave. Since the voltage across the micro-LED does not rise enough for significant current to flow through the micro-LED, light output is low or non-existent, and PWM is ineffective.

FIG. 7 at “D” illustrates the effect of including the fixed bias source (but not the pre-bias source) illustrated in FIG. 6. The fixed bias current keeps the parasitic capacitance of the micro-LED charged and the voltage across the micro-LED near the “knee” [onset of a rapidly increasing section] of the micro-LED i(v) curve. When the same small PWM signal as in “C” is applied, the voltage change across the micro-LED occurs in a steeply rising section of the micro-LED curve. This permits PWM signals to remain effective at low light levels and therefore improves display dynamic range.

FIG. 8 illustrates the effect of including both pre-bias and fixed bias current sources in the circuit of FIG. 6. Semiconductor process variations lead to differences in i(v) characteristics of different micro-LEDs in an array. These process variations mean that for some micro-LEDs a fixed bias alone may improve the situation of FIG. 7C, but not enough to achieve the desired behavior of FIG. 7D. A solution to this problem is to include both the pre-bias source and pre-bias switch shown in FIG. 6.

In FIG. 8, time periods are labeled “a”, “b” and “c”. (These labels are not related to “A”, “B”, “C” or “D” in FIG. 7.) Note that the horizontal time axis is not to scale in FIG. 8. During time period “a”, a fixed bias current source keeps the voltage across a micro-LED near, but below a minimum level required to generate light output. (The fixed bias also has the beneficial effect of protecting the high voltage level shifter in the circuit of FIG. 6.) During time period “b”, the pre bias switch of FIG. 6 turns on the pre-bias current source. The pre-bias current brings the voltage across the micro-LED very close to, or even above the level required to generate light output. During time period “c”, the PWM switch of FIG. 6 turns on a PAM current to turn on the micro-LED. Time period “a”, represents all the time before the “b”, “c” sequence next occurs. This pre-bias and fixed bias scheme ensures that the micro-LED is turned on for nearly the entire duration of the PWM current pulse even when the PAM current level is low. This improves display dynamic range for dim images. The “a”, “b”, “c” sequence may be repeated for each bit in a PWM bit sequence.

In one example, the pre-bias current source of FIG. 6 may supply about 1 nA, while the fixed current source may supply about 0.01 nA. The pre-bias may be applied (in step “b”) for about 400 ns while the PWM pulse duration may be as short as about 100 μs or as long as about 4 ms, depending on, for example, whether a binary-weighted PWM scheme is used. In some cases a PWM pulse may be as much as 1,000 times longer than the pre-bias pulse. Even if the micro-LED is turned on during the entire pre-bias pulse, the slightly increased micro-LED illumination time is not noticeable to human observers. In FIG. 8 the pre-bias turns on the micro-LED for about half of the pre-bias pulse, or about 200 ns in this example. In a typical system the magnitude of the pre-bias current may be at least 10, or even 1000, times more than the magnitude of the fixed bias current, the wide range being a consequence of the nonlinear dependence of light output on drive current. The duration of the pre-bias pulse may be less than 2% of the duration of the video frame time.

The GaN micro-LED display described herein benefits from the improved power supply rejection ratio of the circuit of FIG. 5, and/or from the improved dynamic range offered by the fixed and pre-bias current sources connected in parallel with the PWM drive current for each micro-LED. These features may be employed independently or together. The bias sources ensure that PWM modulation is effective even when the overall displayed light level is low.

As used herein, the source and drain of a field-effect transistor are referred to as the “power” terminals of the field-effect transistor, and the gate is referred to as a the “control” terminal of the field-effect transistor. As used herein, when transistors are described as being “connected in series” or “connected in parallel” with another transistor or element, it is the connection of power terminals that is described. As such, if two transistors are connected in series, a power terminal of one of the transistors is connected to a power terminal of the other transistor, so that a series current path is formed through the two transistors.

As mentioned above, in some embodiments, a light-emitting diode (LED) display, with improved uniformity of illumination, includes: an array 120 of GaN micro-LEDs; and a complementary metal-oxide-semiconductor (CMOS) backplane 110, the array being hybrid bonded to the CMOS backplane, the array including a first LED 405, the CMOS backplane including: a first current source circuit; and a gate control circuit, the first current source circuit including: an n-channel field effect transistor 505; and a p-channel field effect transistor 510, the n-channel field effect transistor, the p-channel field effect transistor, and the first LED being connected in series, the source of the n-channel field effect transistor being connected to the source of the p-channel field effect transistor, the gate control circuit having a first output connected to the gate of the n-channel field effect transistor and a second output connected to the gate of the p-channel field effect transistor.

In some embodiments, the gate control circuit includes a first diode-connected field effect transistor 515 connected in series with a second diode-connected field effect transistor 520.

In some embodiments, the gate control circuit further includes a current control circuit (including, e.g., in the circuit of FIG. 5, the current sources PAM(1) and PAM(2)) for controlling: a current flowing through the first diode-connected field effect transistor 515, and a current flowing through the second diode-connected field effect transistor 520.

In some embodiments, the gate control circuit further includes a voltage control circuit for controlling a voltage at a common node Vₚ of the first diode-connected field effect transistor and the second diode-connected field effect transistor.

In some embodiments, the first diode-connected field effect transistor 515 is an n-channel field effect transistor, and the second diode-connected field effect transistor 520 is a p-channel field effect transistor.

In some embodiments, the source of the first diode-connected field effect transistor is connected to the source of the second diode-connected field effect transistor.

In some embodiments: the array further includes a second LED; the CMOS backplane further includes a second current source circuit; the second current source circuit includes: an n-channel field effect transistor, and a p-channel field effect transistor; and the n-channel field effect transistor of the second current source circuit, the p-channel field effect transistor of the second current source circuit, and the second LED are connected in series. For example, in the array of FIG. 1, a plurality of LEDs may be connected to similar or shared drive circuits such as those of FIG. 5.

In some embodiments: the first output of the gate control circuit is connected to the gate of the n-channel field effect transistor of the second current source circuit, and the second output of the gate control circuit is connected to the gate of the p-channel field effect transistor of the second current source circuit. For example, current may be supplied to each LED by a respective current source circuit, and groups of LEDs (e.g., rows or columns of the display of FIG. 1) may share a gate control circuit.

In some embodiments, a light-emitting diode (LED) display includes: an array of GaN micro-LEDs; and a complementary metal-oxide-semiconductor (CMOS) backplane, the array being hybrid bonded to the CMOS backplane, the array including a first LED, the CMOS backplane including a first drive circuit, the first drive circuit including: a first current supply, the first current supply being a switched current supply, configured to supply, when switched on, a first current to the first LED; and a second current supply, capable of supplying a second current to the first LED when the first current supply is switched off. For example, in the circuit of FIG. 6, (i) the first current supply may include the PWM switch and the transistor connected between the positive supply and the PWM switch, and (ii) the second current supply may include the pre-bias switch and the 1 nA bias current supply.

In some embodiments, the second current supply is a switched current supply; for example, the second current supply may be switched on or off by the pre-bias switch.

In some embodiments, the first drive circuit is configured to switch on the second current supply at least 0.01 microseconds before switching on the first current supply.

In some embodiments, the CMOS backplane further includes a third current supply (e.g., the 0.01 nA bias supply of FIG. 6), capable of supplying a third current to the first LED when the first current supply is switched off, the third current being sufficient to produce a forward voltage drop, across the first LED, of at least one half of a bandgap voltage of the first LED.

In some embodiments, the second current is sufficient to produce a forward voltage drop, across the first LED, of at least two thirds of a bandgap voltage of the first LED.

What is claimed is:

1. A light-emitting diode (LED) display with improved uniformity of illumination, the LED display comprising:
an array of GaN micro-LEDs; and
a complementary metal-oxide-semiconductor (CMOS) backplane,
the array being hybrid bonded to the CMOS backplane,
the array comprising a first LED,
the CMOS backplane comprising:
a first current source circuit; and
a gate control circuit,
the first current source circuit comprising:
an n-channel field effect transistor; and
a p-channel field effect transistor,
the n-channel field effect transistor, the p-channel field effect transistor, and the first LED being connected in series,
the source of the n-channel field effect transistor being connected to the source of the p-channel field effect transistor,
the gate control circuit having a first output connected to the gate of the n-channel field effect transistor and a second output connected to the gate of the p-channel field effect transistor.

2. The LED display of claim 1, wherein the gate control circuit comprises a first diode-connected field effect transistor connected in series with a second diode-connected field effect transistor.

3. The LED display of claim 2, wherein the gate control circuit further comprises a current control circuit for controlling:
a current flowing through the first diode-connected field effect transistor, and
a current flowing through the second diode-connected field effect transistor.

4. The LED display of claim 3, wherein the gate control circuit further comprises a voltage control circuit for controlling a voltage at a common node of the first diode-connected field effect transistor and the second diode-connected field effect transistor.

5. The LED display of claim 2, wherein the first diode-connected field effect transistor is an n-channel field effect transistor, and the second diode-connected field effect transistor is a p-channel field effect transistor.

6. The LED display of claim 5, wherein the source of the first diode-connected field effect transistor is connected to the source of the second diode-connected field effect transistor.

7. The LED display of claim 2, wherein:
the array further comprises a second LED;
the CMOS backplane further comprises a second current source circuit;
the second current source circuit comprises:
an n-channel field effect transistor, and
a p-channel field effect transistor; and
the n-channel field effect transistor of the second current source circuit, the p-channel field effect transistor of the second current source circuit, and the second LED are connected in series.

8. The LED display of claim 7, wherein:
the first output of the gate control circuit is connected to the gate of the n-channel field effect transistor of the second current source circuit, and
the second output of the gate control circuit is connected to the gate of the p-channel field effect transistor of the second current source circuit.

9. A light-emitting diode (LED) display comprising:
an array of GaN micro-LEDs; and
a complementary metal-oxide-semiconductor (CMOS) backplane,
the array being hybrid bonded to the CMOS backplane,
the array comprising a first LED,
the CMOS backplane comprising a first drive circuit,
the first drive circuit comprising:
a first current supply, the first current supply being a switched current supply, configured to supply, when switched on, a first current to the first LED; and
a second current supply, capable of supplying a second current to the first LED when the first current supply is switched off.

10. The LED display of claim 9, wherein the second current is sufficient to produce a forward voltage drop, across the first LED, of at least two thirds of a bandgap voltage of the first LED.

11. The LED display of claim 9, wherein the second current supply is a switched current supply.

12. The LED display of claim 11, wherein the first drive circuit is configured to switch on the second current supply at least 0.01 microseconds before switching on the first current supply.

13. The LED display of claim 9, wherein the CMOS backplane further comprises a third current supply, capable of supplying a third current to the first LED when the first current supply is switched off, the third current being sufficient to produce a forward voltage drop, across the first LED, of at least one half of a bandgap voltage of the first LED.

14. The LED display of claim 13, wherein the second current is sufficient to produce a forward voltage drop, across the first LED, of at least two thirds of a bandgap voltage of the first LED.

15. The LED display of claim 13 wherein the second current supply provides at least 10 times more current than the third current supply.

16. The LED display of claim 13 wherein the second current supply provides at least 1000 times more current than the third current supply.

17. The LED display of claim 15 wherein the second current is applied for less than 2% of the duration of a video frame time.
